(19) United States
(12) Patent Application Publication
(10) Pub. No.: US 2024/0266173 A1
(43) Pub. Date: Aug. 8, 2024

(54) METHOD FOR MANUFACTURING TRANSISTOR DEVICE, AND TRANSISTOR DEVICE

(71) Applicant: BITMAIN TECHNOLOGIES INC., Beijing (CN)

(72) Inventors: Heng WU, Beijing (CN); Hao Yan, Beijing (CN); Yanfeng Wang, Beijing (CN); Xuejie Shi, Beijing (CN); Yu Pu, Beijing (CN); Guanxian Lin, Beijing (CN)

(21) Appl. No.: 18/431,815

(22) Filed: Feb. 2, 2024

(30) Foreign Application Priority Data
Feb. 3, 2023 (CN) 202310118993.1

(51) Int. Cl. H01L 21/265; H01L 27/06; H01L 29/06; H01L 29/66

(52) U.S. Cl. CPC H01L 21/265; H01L 27/0617; H01L 29/0607; H01L 29/66545

(57) ABSTRACT

Embodiments of the present disclosure provide a method for manufacturing a transistor device, and a transistor device. The method for manufacturing a transistor device includes: injecting, into a channel of at least one first transistor located in an electrical break (EB) region, doping ions of a different type from the first transistor, and/or injecting, into a channel of at least one second transistor located outside the EB region, doping ions of a same type as the second transistor; and forming the transistor device based on the first transistor and the second transistor into which doping ions have been injected.

### CROSS-REFERENCE TO RELATED APPLICATION

This application claims priority to Chinese application No. 202310118993.1, filed on Feb. 3, 2023, which is incorporated by reference in its entirety.

### TECHNICAL FIELD

The present disclosure relates to the field of microelectronic devices and, in particular, to a method for manufacturing a transistor device, and a transistor device.

### BACKGROUND

In the related art, Electrical Break (EB) is generally used to implement isolation of transistor cells. For example, a voltage is applied to a channel of a P-type transistor and a channel of an N-type transistor to turn off the corresponding transistors, so as to implement cell-to-cell isolation. However, in some scenarios (such as in an ultra-low power design), such a method does not produce sufficient blocking effect on a leakage current, and there is still a certain degree of leakage current, resulting in high overall power consumption of a chip.

In addition, an adjustment to a threshold voltage of a transistor in a device is usually made using a method of adjusting a metal work function of a high-K metal gate or adjusting a high-K dielectric, in which method an adjustment range of the threshold voltage is limited, making it impossible to reduce the threshold voltage to a lower level.

### SUMMARY

Embodiments of the present disclosure provide a method for manufacturing a transistor device, and a transistor device.

In a first aspect, an embodiment of the present disclosure provides a method for manufacturing a transistor device. The method includes:
injecting, into a channel of at least one first transistor located in an electrical break (EB) region, doping ions of a different type from the first transistor, and/or injecting, into a channel of at least one second transistor located outside the EB region, doping ions of a same type as the second transistor; and
forming the transistor device based on the first transistor and the second transistor into which doping ions have been injected.

Based on the above solution, a type of the transistor includes: a P type or an N type:
the injecting, into the channel of the at least one first transistor located in the electrical break (EB) region, the doping ions of the different type from the first transistor, and/or the injecting, into the channel of the at least one second transistor located outside the EB region, the doping ions of the same type as the second transistor includes:
injecting N-type doping ions into a channel of at least one P-field effect transistor (PFET) located in the EB region and a channel of at least one N-field effect transistor (NFET) located outside the EB region; and
injecting P-type doping ions into a channel of at least one NFET located in the EB region and a channel of at least one PFET located outside the EB region.

Based on the above solution, the injecting the N-type doping ions into the channel of the at least one P-field effect transistor (PFET) located in the EB region and the channel of the at least one N-field effect transistor (NFET) located outside the EB region includes:
opening, through a photolithography process, a gate region of the at least one PFET located in the EB region and a gate region of the at least one NFET located outside the EB region; and
injecting, through the gate region of the PFET, N-type doping ions into the channel of the PFET, and injecting, through the gate region of the NFET, N-type doping ions into the channel of the NFET.

Based on the above solution, the injecting the P-type doping ions into the channel of the at least one NFET located in the EB region and the channel of the at least one PFET located outside the EB region includes:
opening, through a photolithography process, a gate region of the at least one NFET located in the EB region and a gate region of the at least one PFET located outside the EB region; and
injecting, through the gate region of the NFET, P-type doping ions into the channel of the NFET, and injecting, through the gate region of the PFET, P-type doping ions into the channel of the PFET.

Based on the above solution, the method further includes:
removing dummy gate structures that cover the gate regions of the at least one PFET and of the at least one NFET; and
the forming the transistor device based on the first transistor and the second transistor into which doping ions have been injected includes:
forming a metal gate in each of the gate regions of the at least one PFET and the at least one NFET into which doping ions have been injected; and
forming the transistor device based on the PFET and the NFET in which the metal gate is formed.

Based on the above solution, the method further includes:
performing fin reveal processing on the at least one PFET and of the at least one NFET; and
after removing a protective layer from the revealed fin, depositing an oxide layer on the fin; and the photolithography process acts on the oxide layer.

Based on the above solution, the forming the transistor device based on the first transistor and the second transistor into which doping ions have been injected includes:
forming a dummy gate in each of the gate regions of the at least one PFET and the at least one NFET into which doping ions have been injected; and
forming the transistor device based on the PFET and the NFET in which the dummy gate is formed.

Based on the above solution, the P-type doping ions include at least one of the following:
boron ions, boron difluoride ions, aluminum ions, and gallium ions; and
the N-type doping ions include at least one of the following:
phosphorus ions, antimony ions, and arsenic ions.

Based on the above solution, an amount of injection of the doping ions is associated with a current threshold voltage and/or a target threshold voltage of a transistor.

Based on the above solution, a concentration of the doping ions is 10¹² to 10¹⁴/cm², and/or energy of the doping ions is 1 keV to 10 keV.

In a second aspect, an embodiment of the present disclosure provides a transistor device, which is manufactured through the method for manufacturing a transistor device described in one or more of the foregoing technical solutions.

Based on the above solution, the transistor device includes: an inverter.

The technical solutions provided in the embodiments of the present disclosure may have the beneficial effects as follows.

The method for manufacturing a transistor device provided in the embodiment of the present disclosure includes: injecting, into a channel of at least one first transistor located in an electrical break (EB) region, doping ions of a different type from the first transistor, and/or injecting, into a channel of at least one second transistor located outside the EB region, doping ions of a same type as the second transistor; and forming the transistor device based on the first transistor and the second transistor into which doping ions have been injected. In this way, on the one hand, for the transistor in the EB region, the injection of the doping ions of the different type from the transistor into the channel of the transistor reduces the conductivity of the doped channel of the transistor in the EB region, and increases a threshold voltage, thereby providing better isolation between transistors in the EB region, and reducing a leakage current that exists even under the electrical break. On the other hand, for the transistor outside the EB region that is used for logic operations, the injection of the doping ions of the same type as the transistor into the channel of the transistor increases the conductivity of the channel of the transistor, and reduces a threshold voltage of the transistor, thereby reducing a driving voltage of a device and an overall driving voltage of a chip.

### BRIEF DESCRIPTION OF THE DRAWINGS

The accompanying drawings herein are incorporated into and constitute a part of the description, illustrate embodiments consistent with the present disclosure, and are used together with the description to explain the principles of the present disclosure.

FIG. 1 is a schematic flowchart of a method for manufacturing a transistor device according to an exemplary embodiment.

FIG. 2 is a schematic structural diagram of a transistor device according to an exemplary embodiment.

FIG. 3 is a schematic diagram of a circuit structure including a transistor device in the related art according to an exemplary embodiment.

FIG. 4 is a schematic flowchart of a method for manufacturing a transistor device according to an exemplary embodiment.

FIG. 5 is a schematic structural diagram of a transistor device according to an exemplary embodiment.

FIG. 6 is a schematic structural diagram of a transistor device according to an exemplary embodiment.

FIG. 7 is a schematic diagram of a process for a method for manufacturing a transistor device according to an exemplary embodiment.

FIG. 8 is a schematic diagram of a process for a method for manufacturing a transistor device according to an exemplary embodiment.

FIG. 9 is a schematic diagram of a process for a method for manufacturing a transistor device according to an exemplary embodiment.

FIG. 10 is a schematic diagram of a process for a method for manufacturing a transistor device according to an exemplary embodiment.

FIG. 11 is a schematic diagram of a process for a method for manufacturing a transistor device according to an exemplary embodiment.

FIG. 12 is a schematic diagram of a process for a method for manufacturing a transistor device according to an exemplary embodiment.

FIG. 13 is a schematic diagram of a process for a method for manufacturing a transistor device according to an exemplary embodiment.

FIG. 14 is a schematic diagram of a process for a method for manufacturing a transistor device according to an exemplary embodiment.

### DESCRIPTION OF EMBODIMENTS

Exemplary embodiments will be described in detail herein, with examples shown in the accompanying drawings. Unless otherwise indicated, the same numbers in different drawings represent the same or similar elements when the following description refers to the drawings. Implementations described in the following exemplary embodiments do not represent all implementations consistent with the present disclosure. Instead, the implementations are merely examples of apparatuses consistent with some aspects of the present disclosure as detailed in the appended claims.

As shown in FIG. 1, an embodiment of the present disclosure provides a method for manufacturing a transistor device. The method includes:
S110: injecting, into a channel of at least one first transistor located in an electrical break (EB) region, doping ions of a different type from the first transistor, and/or injecting, into a channel of at least one second transistor located outside the EB region, doping ions of a same type as the second transistor; and
S120: forming the transistor device based on the first transistor and the second transistor into which doping ions have been injected.

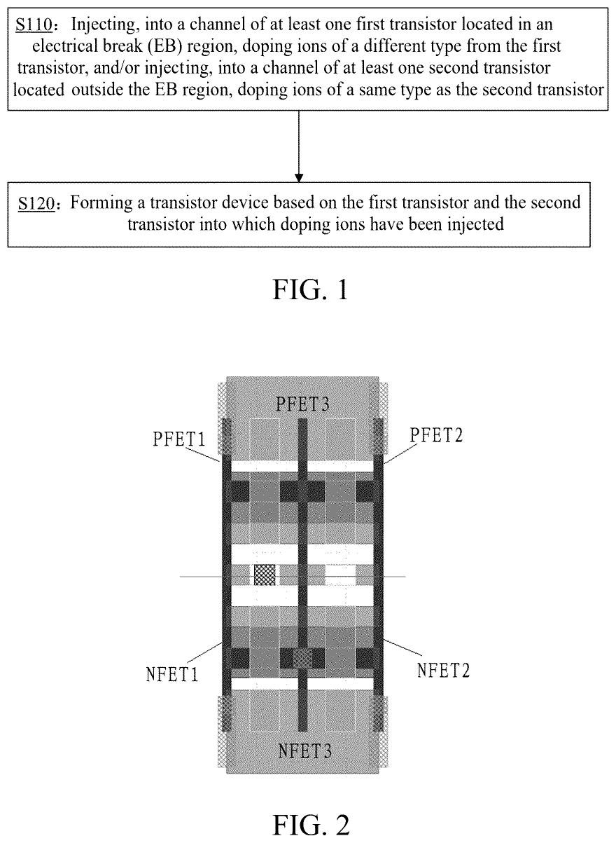

In the embodiment of the present disclosure, the transistor device may be an inverter, such as a D1 inverter. Electrical break (EB) may be applying a voltage to the transistor in the EB region, for example, applying a certain voltage to a gate of the transistor. Exemplarily, as shown in FIG. 2, a voltage VDD is applied to gates of PFET1 and PFET2, and a voltage VSS is applied to gates of NFET1 and NFET2. At this time, PFET1, PFET2, NFET1, and NFET2 are the first transistors located in the EB region, and PFET3 and NFET3 are the second transistors located outside the EB region. A first transistor is a transistor in the transistor device that is used to implement a turn-off isolation function based on the electrical break, and a second transistor may be a transistor in the transistor device that is used for logic operations and other tasks.

In one embodiment, a type of the first transistor located in the EB region may be a P type and/or an N type, for example, the first transistor may be a PFET and/or an NFET, and a type the second transistor located outside the EB region may also be a P type and/or an N type, for example, the second transistor may be a PFET and/or an NFETs, etc.

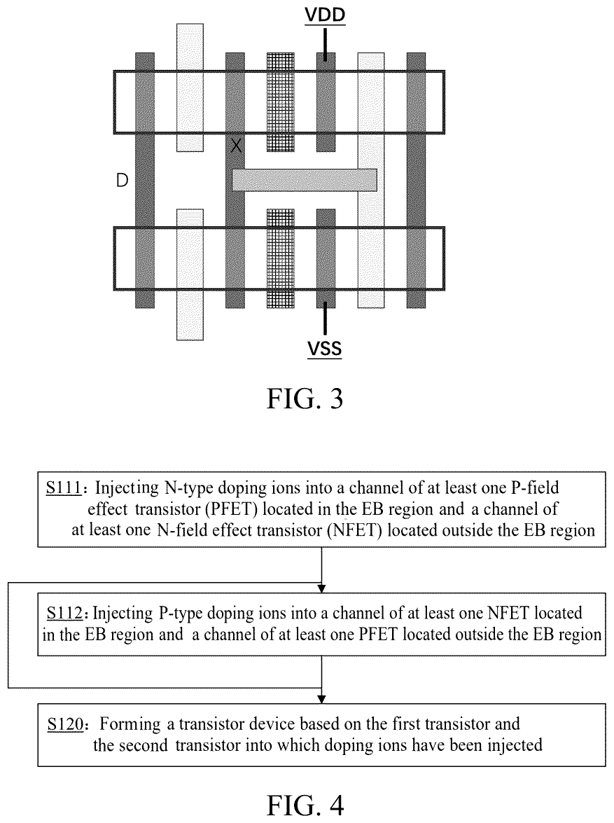

In the related art, as shown in FIG. 3, a voltage VDD is applied to a channel of a transistor PFET, and a voltage VSS is applied to a channel of a transistor NFET, to turn off the corresponding transistors, thereby implementing electrical isolation. When a potential at the input stage D is 0, and a transmission gate is open, the X node will be pulled down to a potential of 0. Under this condition, there will be a leakage current from VDD to the X node (even with a high potential at a gate of the PFET, there is a large leakage current). This leakage current may affect the charge on the X node, resulting in a change of a saved state of the X node, and causing error code. Similarly, with a high level at the input stage D, there will be a leakage current from the X node to VSS, which may also cause a change of the state of the X node. Furthermore, due to the existence of this leakage current, the overall static power consumption of a chip is increased, resulting in unnecessary losses. In an ultra-low power circuit design, due to low VDD, this leakage current accounts for a high proportion of the overall chip power consumption.

In one embodiment, the first transistor in the EB region may include a P-type transistor and an N-type transistor which exist in pairs. For example, the EB region may contain one pair of PFET and NFET, and may also contain two or more pairs of PFET and NFET, etc.

In one embodiment, the injecting, into the channel of the at least one first transistor located in the EB region, the doping ions of the different type from the first transistor may include: injecting N-type doping ions into a channel of at least one PFET located in the EB region, and injecting P-type doping ions into a channel of at least one NFET located in the EB region. The N-type doping ions may include phosphorus ions, antimony ions, arsenic ions, etc., and the P-type doping ions may include boron ions, boron difluoride (BF2) ions, aluminum ions, gallium ions, etc.

In this way, the injection of the doping ions of the different type into the channel of the transistor located in the EB region reduces the conductivity of the channel, and increases a Threshold Voltage (Vt) of the transistor, thereby providing a better isolation effect of EB, and reducing a generated leakage current. It can be understood that the greater the amount of injected doping ions is, the more the conductivity is reduced, the more the threshold voltage of the transistor is increased, and the less the leakage current is generated.

In one embodiment, the second transistor outside the EB region may be a transistor used for logic operations, etc., and may include, for example, a transistor with an Extremely Low Threshold Voltage (ELVT) requirement.

In one embodiment, the injecting, into the channel of the at least one second transistor located outside the EB region, the doping ions of the same type as the second transistor may include: injecting P-type doping ions into a channel of at least one PFET located outside the EB region, and injecting N-type doping ions into a channel of at least one NFET located outside the EB region.

In this way; the injection of the doping ions of the same type into the channel of the transistor located outside the EB region increases the conductivity of the channel, and reduces a Threshold Voltage (Vt) of the transistor, thereby reducing a driving voltage required for operation of the transistor device and the chip. It can be understood that the greater the amount of injected doping ions is, the more the conductivity is increased, the more the threshold voltage of the transistor is reduced, and the lower the required driving voltage is.

In the related art, in the electrical break (EB) technical solution, an input stage S/D region adjacent to an EB device is required to be changed to a fixed-level electrode, while an output stage of a transmission gate remains isolated from a source and a drain of the EB device, which realizes that data stored in the transmission gate does not change due to a leakage current in a continuous active region (Continuous On Diffusion, CNOD). However, such a method may lead to a large increase in layout area, which cannot fully meet current requirements of micro technologies.

In this way, not only can the threshold voltage of the transistor in the EB region be increased, but also the isolation effect can be improved and the leakage current can be reduced, without an increase in chip layout area, simply by injecting the doping ions. In addition, the threshold voltage of the second transistor in the ELVT region can be better reduced, thereby further optimizing the operating efficiency of the transistor device.

In some embodiments, a type of the transistor includes: a P type or an N type.

As shown in FIG. 4, step S110 may include:
S111: injecting N-type doping ions into a channel of at least one P-field effect transistor (PFET) located in the EB region and a channel of at least one N-field effect transistor (NFET) located outside the EB region; and
S112: injecting P-type doping ions into a channel of at least one NFET located in the EB region and a channel of at least one PFET located outside the EB region.

In the embodiment of the present disclosure, the injecting N-type doping ions into a channel of at least one P-field effect transistor (PFET) located in the EB region and a channel of at least one N-field effect transistor (NFET) located outside the EB region may include: determining an amount of injection of the N-type doping ions to be injected based on a current threshold voltage and/or a target threshold voltage of the PFET or the NFET. For example, the higher the current threshold voltage is, the greater the amount of injection may be: alternatively, the lower the target threshold voltage is, or the greater a difference between the target threshold voltage and the current threshold voltage is, the greater the amount of injection may be, and thus, the more the conductivity of the channel of the PFET in the EB region is increased, and the more the conductivity of the channel of the NFET outside the EB region is reduced.

In one embodiment, accordingly, the injecting P-type doping ions into a channel of at least one NFET located in the EB region and a channel of at least one PFET located outside the EB region may include: determining an amount of injection of the P-type doping ions to be injected based on a current threshold voltage and/or a target threshold voltage of the NFET or the PFET. For example, the higher the current threshold voltage is, the greater the amount of injection may be: alternatively, the lower the target threshold voltage is, or the greater a difference between the target threshold voltage and the current threshold voltage is, the greater the amount of injection may be, and thus, the more the conductivity of the channel of the NFET in the EB region is increased, and the more the conductivity of the channel of the PFET outside the EB region is reduced.

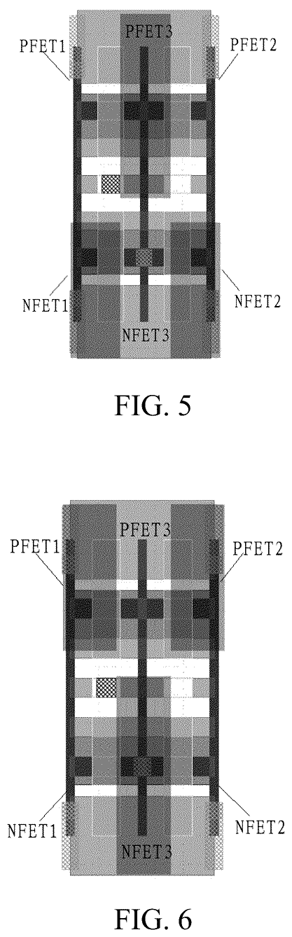

In one embodiment, the N-type or P-type doping ions may be injected into the channel through a photolithography process on a mask. For example, as shown in FIG. 5, the injecting N-type doping ions into the channel of the PFET located in the EB region and the channel of the NFET located outside the EB region is injecting the N-type doping ions into PFET1, PFET2 and NFET3, which may be injecting the N-type doping ions into the channels by covering PFET3, NFET1 and NFET2 through a photolithography mask and opening the gate regions of PFET1, PFET2 and NFET3. The shaded areas in FIG. 5 are covered areas, for example, PFET3, NFET1, and NFET2 are covered by photoresist.

In one embodiment, as shown in FIG. 6, the injecting P-type doping ions into the channel of the NFET located in the EB region and the channel of the PFET located outside the EB region is injecting the P-type doping ions into PFET3, NFET1 and NFET2, which may be injecting the P-type doping ions into the channels by covering PFET1, PFET2 and NFET3 by a photolithography mask and opening the gate regions of PFET3, NFET1 and NFET2. The shaded areas in FIG. 6 are covered areas, for example, PFET1, PFET2 and NFET3 are covered by photoresist.

In this way, the injection of one type of doping ions into multiple channels of transistors in and outside multiple EB regions can be completed at the same time in a single injection, thereby saving steps of a manufacturing process.

In some embodiments, step S111 may include:
opening, through a photolithography process, a gate region of the at least one PFET located in the EB region and a gate region of the at least one NFET located outside the EB region; and
injecting, through the gate region of the PFET, N-type doping ions into the channel of the PFET, and injecting, through the gate region of the NFET, N-type doping ions into the channel of the NFET.

In the embodiment of the present disclosure, the gate regions of the PFET located outside the EB region and the NFET located in the EB region may be covered with photoresist, and the gate region of the at least one PFET located in the EB region and the gate region of the at least one NFET located outside the EB region may be opened through the photolithography process.

In some embodiments, step S111 may include:
opening, through a photolithography process, a gate region of the at least one NFET located in the EB region and a gate region of the at least one PFET located outside the EB region; and
injecting, through the gate region of the NFET, P-type doping ions into the channel of the NFET, and injecting, through the gate region of the PFET, P-type doping ions into the channel of the PFET.

In the embodiment of the present disclosure, the gate regions of the NFET located outside the EB region and the PFET located in the EB region may be covered with photoresist, and the gate region of the at least one NFET located in the EB region and the gate region of the at least one PFET located outside the EB region may be opened through the photolithography process.

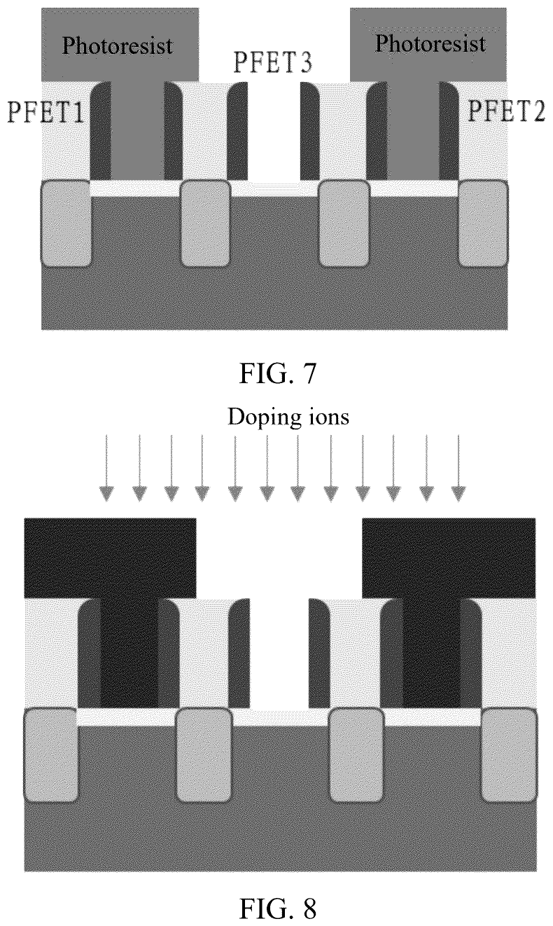

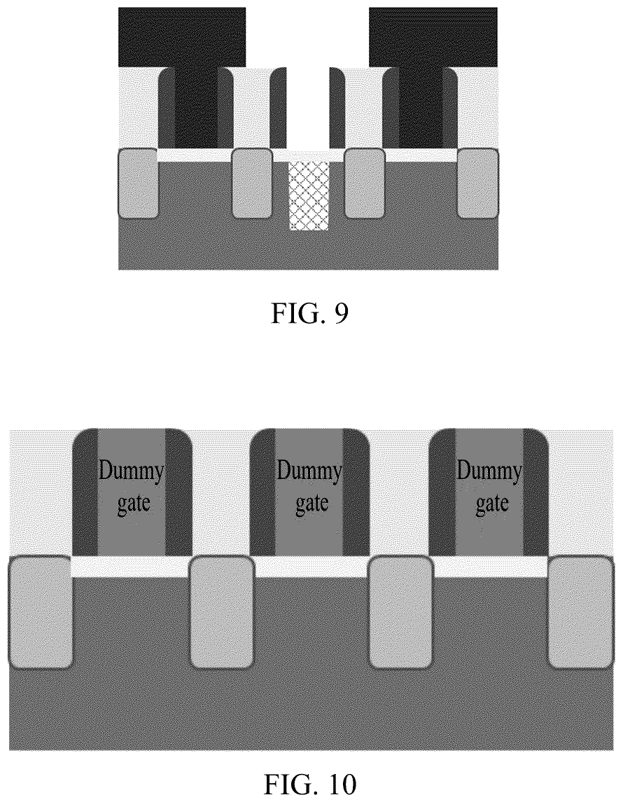

Exemplarily, as shown in FIG. 7, the gate regions of PFET1 and PFET2 located in the EB region are covered with photoresist, and the gate region of PFET3 located outside the EB region is opened through the photolithography process. As shown in FIG. 8, P-type doping ions are injected into the channel of PFET3 through the gate region. FIG. 9 is an illustration after the P-type doping ions are injected.

In some embodiments, the method further includes:
removing dummy gate structures that cover the gate regions of the at least one PFET and of the at least one NFET.

Step S120 may include:
forming a metal gate in each of the gate regions of the at least one PFET and the at least one NFET into which doping ions have been injected; and
forming the transistor device based on the PFET and the NFET in which the metal gate is formed.

In the embodiment of the present disclosure, before the operation step of injecting doping ions included in step S110, the dummy gate structures that cover the gate regions of the at least one PFET and the at least one NFET may be removed first. For example, dummy gate structures for all PFETs and NFETs in the transistor device may be removed. As shown in FIG. 10, the dummy gate structures for the gate regions of the PFETs are removed.

In one embodiment, after the dummy gate structures are removed, gate regions of some of the PFETs and NFETs may be covered by photoresist, and corresponding doping ions may be injected into the channels through gate regions of uncovered PFETs and NFETs. For further details, reference may be made to the contents of the foregoing embodiments, which are not repeated here.

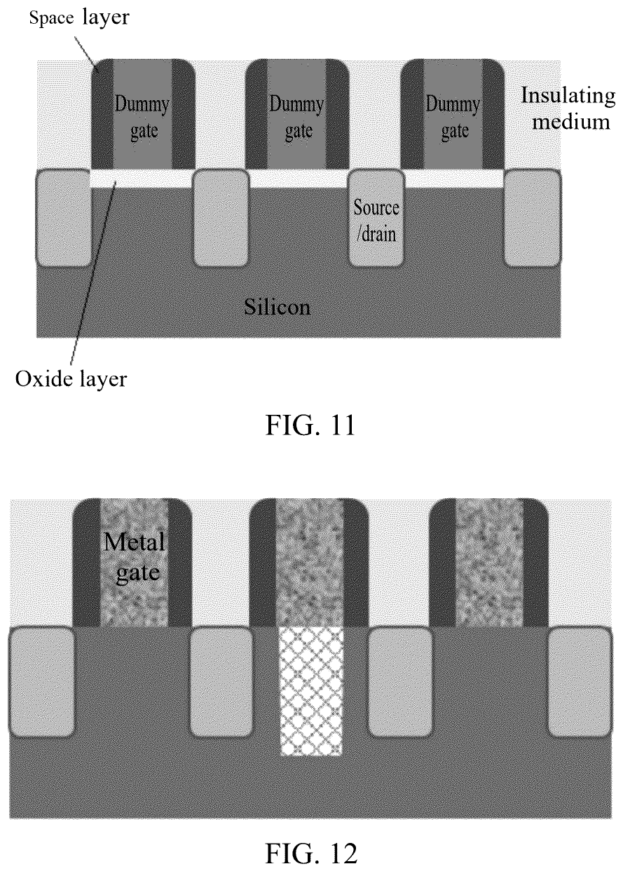

In one embodiment, as shown in FIG. 11, before removal of the dummy gate structures, the device may be planarized, e.g., by chemically and mechanically planarizing an insulating medium of the mask.

In some embodiments, as shown in FIG. 12, after the injection of the doping ions is completed, a metal gate may be further formed in a gate region, where the metal gate may be a high-K metal gate, etc.

In some embodiments, the method further includes:
revealing a fin of the at least one PFET and of the at least one NFET; and
after removing a protective layer from the revealed fin, depositing an oxide layer on the fin. The photolithography process acts on the oxide layer.

In the embodiment of the present disclosure, the fin reveal may be a fin reveal process in a standard process. After the fin reveal process, the protective layer may be removed from the revealed fin, and the oxide layer may be deposited on the fin. Before the operation step of injecting doping ions included in step S110, when the dummy gate structures have not yet been formed, operations of fin reveal processing, removal of a fin protective layer and deposition of a fin oxide may be further performed.

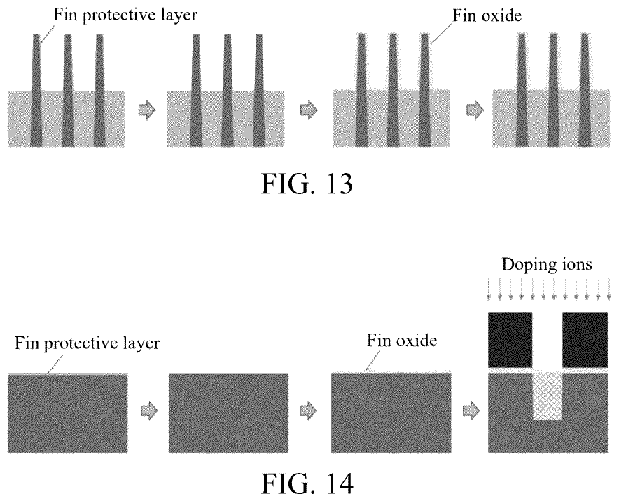

In one embodiment, FIG. 13 and FIG. 14 are respectively schematic flowcharts of operation along two vertical directions, of fin reveal, removal of a fin protective layer, deposition of a fin oxide and injection of doping ions.

In one embodiment, after completion of the processing of fin reveal, removal of a fin protective layer, deposition of a fin oxide and injection of doping ions, step S120 may include:
forming a dummy gate in each of the gate regions of the at least one PFET and the at least one NFET into which doping ions have been injected; and
forming the transistor device based on the PFET and the NFET in which the dummy gate is formed.

In some embodiments, the P-type doping ions may include at least one of the following:
boron ions, boron difluoride ions, aluminum ions, and gallium ions; and
the N-type doping ions may include at least one of the following:
phosphorus ions, antimony ions, and arsenic ions.

In some embodiments, an amount of injection of the doping ions may be associated with a current threshold voltage and/or a target threshold voltage of a transistor.

In one embodiment, an amount of injection of the N-type doping ions to be injected may be determined based on a current threshold voltage and/or a target threshold voltage of the PFET located in the EB region or the NFET located outside the EB region. For example, the higher the current threshold voltage is, the greater the amount of injection may be: alternatively, the lower the target threshold voltage is, or the greater a difference between the target threshold voltage and the current threshold voltage is, the greater the amount of injection may be, and thus, the more the conductivity of the channel of the PFET in the EB region is increased, and the more the conductivity of the channel of the NFET outside the EB region is reduced.

In one embodiment, an amount of injection of the P-type doping ions to be injected may be determined based on a current threshold voltage and/or a target threshold voltage of the NFET located in the EB region or the PFET located outside the EB region. For example, the higher the current threshold voltage is, the greater the amount of injection may be: alternatively, the lower the target threshold voltage is, or the greater a difference between the target threshold voltage and the current threshold voltage is, the greater the amount of injection may be, and thus, the more the conductivity of the channel of the NFET in the EB region is increased, and the more the conductivity of the channel of the PFET outside the EB region is reduced.

In one embodiment, a concentration and/or energy of the doping ions to be injected may be a fixed value or a fixed range, or may be determined based on the current threshold voltage and/or the target threshold voltage of the transistor. Exemplarily, the concentration of the doping ions to be injected may be 10¹² to 10¹⁴/cm², and/or the energy of the doping ions may be 1 keV to 10 keV, etc., where 10¹² to 10¹⁴/cm² may indicate that 10¹² to 10¹⁴ ions are injected per square centimeter of area.

An embodiment of the present disclosure provides a transistor device, which is manufactured through the method for manufacturing a transistor device described in one or more of the foregoing technical solutions.

In some embodiments, the transistor device includes: an inverter.

Here, the inverter may be a D1 inverter, etc.

Other implementations of the present disclosure would readily occur to a person skilled in the art after considering the description and practicing the disclosure herein. The present disclosure is intended to cover any variations, uses or adaptation changes of the present disclosure, which follow the general principles of the present disclosure and include common general knowledge or customary technical means in the art that are not disclosed in the present disclosure. The description and embodiments are merely to be regarded exemplary, while the true scope and spirit of the present disclosure are indicated by the claims below.

It should be understood that the present disclosure is not limited to the precise structures described above and shown in the accompanying drawings, and various modifications and changes may be made without departing from the scope thereof. The scope of the present disclosure is limited only by the appended claims.

What is claimed is:

1. A method for manufacturing a transistor device, comprising:
injecting, into a channel of at least one first transistor located in an electrical break (EB) region, doping ions of a different type from the first transistor, and/or injecting, into a channel of at least one second transistor located outside the EB region, doping ions of a same type as the second transistor; and
forming the transistor device based on the first transistor and the second transistor into which doping ions have been injected.

2. The method according to claim 1, wherein a type of the transistor comprises: a P type or an N type:
the injecting, into the channel of the at least one first transistor located in the electrical break (EB) region, the doping ions of the different type from the first transistor, and/or the injecting, into the channel of the at least one second transistor located outside the EB region, the doping ions of the same type as the second transistor comprises:
injecting N-type doping ions into a channel of at least one P-field effect transistor (PFET) located in the EB region and a channel of at least one N-field effect transistor (NFET) located outside the EB region; and
injecting P-type doping ions into a channel of at least one NFET located in the EB region and a channel of at least one PFET located outside the EB region.

3. The method according to claim 2, wherein the injecting the N-type doping ions into the channel of the at least one P-field effect transistor (PFET) located in the EB region and the channel of the at least one N-field effect transistor (NFET) located outside the EB region comprises:
opening, through a photolithography process, a gate region of the at least one PFET located in the EB region and a gate region of the at least one NFET located outside the EB region; and
injecting, through the gate region of the PFET, N-type doping ions into the channel of the PFET, and injecting, through the gate region of the NFET, N-type doping ions into the channel of the NFET.

4. The method according to claim 2, wherein the injecting the P-type doping ions into the channel of the at least one NFET located in the EB region and the channel of the at least one PFET located outside the EB region comprises:
opening, through a photolithography process, a gate region of the at least one NFET located in the EB region and a gate region of the at least one PFET located outside the EB region; and
injecting, through the gate region of the NFET, P-type doping ions into the channel of the NFET, and injecting, through the gate region of the PFET, P-type doping ions into the channel of the PFET.

5. The method according to claim 3, wherein the method further comprises:
removing dummy gate structures that cover the gate regions of the at least one PFET and of the at least one NFET; and
the forming the transistor device based on the first transistor and the second transistor into which doping ions have been injected comprises:
forming a metal gate in each of the gate regions of the at least one PFET and the at least one NFET into which doping ions have been injected; and
forming the transistor device based on the PFET and the NFET in which the metal gate is formed.

6. The method according to claim 4, wherein the method further comprises:
removing dummy gate structures that cover the gate regions of the at least one PFET and of the at least one NFET; and
the forming the transistor device based on the first transistor and the second transistor into which doping ions have been injected comprises:
forming a metal gate in each of the gate regions of the at least one PFET and the at least one NFET into which doping ions have been injected; and
forming the transistor device based on the PFET and the NFET in which the metal gate is formed.

7. The method according to claim 3, wherein the method further comprises:
performing fin reveal processing on the at least one PFET and of the at least one NFET; and
after removing a protective layer from the revealed fin, depositing an oxide layer on the fin; and the photolithography process acts on the oxide layer.

8. The method according to claim 4, wherein the method further comprises:
performing fin reveal processing on the at least one PFET and of the at least one NFET; and
after removing a protective layer from the revealed fin, depositing an oxide layer on the fin; and the photolithography process acts on the oxide layer.

9. The method according to claim 7, wherein the forming the transistor device based on the first transistor and the second transistor into which doping ions have been injected comprises:
forming a dummy gate in each of the gate regions of the at least one PFET and the at least one NFET into which doping ions have been injected; and
forming the transistor device based on the PFET and the NFET in which the dummy gate is formed.

10. The method according to claim 8, wherein the forming the transistor device based on the first transistor and the second transistor into which doping ions have been injected comprises:
forming a dummy gate in each of the gate regions of the at least one PFET and the at least one NFET into which doping ions have been injected; and
forming the transistor device based on the PFET and the NFET in which the dummy gate is formed.

11. The method according to claim 2, wherein the P-type doping ions comprise at least one of the following:
boron ions, boron difluoride ions, aluminum ions, and gallium ions; and
the N-type doping ions comprise at least one of the following:
phosphorus ions, antimony ions, and arsenic ions.

12. The method according to claim 1, wherein an amount of injection of the doping ions is associated with a current threshold voltage and/or a target threshold voltage of a transistor.

13. The method according to claim 1, wherein a concentration of the doping ions is 10¹² to 10¹⁴/cm², and/or energy of the doping ions is 1 keV to 10 keV.

14. A transistor device, which is manufactured through the method for manufacturing a transistor device according to claim 1.

15. The transistor device according to claim 14, wherein the transistor device comprises: an inverter.
